(19) United States
(12) Patent Application Publication
(10) Pub. No.: US 2014/0029764 A1
(43) Pub. Date: Jan. 30, 2014

(54) VIRTUAL MACHINE-BASED SOUND CONTROL FOR COMPUTERIZED DEVICES IN A NETWORKED COMPUTING ENVIRONMENT

(71) Applicants: San Sun PARK, Suwon-si (KR); Sang Deuk SHIM, Viwang-si (KR); Yoon Hee SHIN, Seoul (KR); Eun Young CHOI, Anyang-si (KR); Sang Hyun KIM, Paju-si (KR)

(72) Inventors: San Sun PARK, Suwon-si (KR); Sang Deuk SHIM, Viwang-si (KR); Yoon Hee SHIN, Seoul (KR); Eun Young CHOI, Anyang-si (KR); Sang Hyun KIM, Paju-si (KR)

(73) Assignee: LG CNS CO., LTD., Seoul (KR)

(21) Appl. No.: 13/556,481

(22) Filed: Jul. 24, 2012

(51) Int. Cl. H03G 1/00

(52) U.S. Cl. CPC H03G 1/00
USPC 381/104

(57) ABSTRACT

In general, embodiments of the present invention provide an approach for VM-based sound control (e.g., volume control, playback, recording, etc.) for computerized/electronic devices (e.g., personal computers (PCs), tablets, smart phones, media players, etc) in a networked computing environment (e.g. a cloud computing environment). In a typical embodiment, a system/architecture is provided that comprises a virtual machine (VM) in communication with a computerized device (e.g., a PC) over a network (e.g., a cloud computing network). These components each comprise elements that provide for optimal control of recording and playing back of sounds.

### TECHNICAL FIELD

In general, the present invention relates to sound control/management for computerized devices (e.g., personal computers (PCs)). Specifically, the present invention relates to virtual machine-based sound control (e.g., playback, volume, etc.) for computerized devices in a networked computing environment (e.g., a cloud computing environment).

### BACKGROUND OF THE INVENTION

Presently, Virtual Desktop Infrastructure (VDI) provides sound control management for device (e.g., personal computers (PCs)) sound cards In previous implementations, a VDI of a virtual sound device may be connected to a client sound device and utilize channels to transmit voice and data environment. Upon playback of a media file, playback data may be downloaded to the user's PC. Challenges may exist, however, in providing for optimal sound function control for the PC. That is, under previous approaches, the PC cannot control artifacts such as volume, which may greatly impact a user's listening experience. Such limitations may have a fundamental impact sound being heard in the normal/natural state.

Heretofore, the following approaches have been attempted:

U.S. Pat. No. 8,117,314 discloses a method for providing remote access to a computer environment provided by a virtual machine which includes the step of receiving authentication information associated with a user of a client machine.

U.S. Pat. No. 8,081,621 discloses a Voice-over-Internet-Protocol (VoIP) system which has improved audio-buffer control. A voice captured by a microphone (mic) is loaded into mic buffers by the sound card and sent to a VoIP application. When a mic buffer arrives from the sound card, a speaker buffer manager is activated.

U.S. Pat. No. 7,971,057 discloses an approach for executing a monitor on a platform, the monitor capable of providing exclusive, secure access to an audio I/O device of the platform, executing a first partition on the platform, providing an audio device model in the first partition by directly mapping the audio I/O device from the monitor to the first partition for applications executing in the first partition, and providing exclusive, secure access to the audio I/O device to a program performing an audio function in a secure mode in the first partition.

U.S. Patent Application No. 20120026923 discloses a personal computer (PC) containing a soft phone connected to a headset by means of a control unit which is connected to a USB gate in the PC. The PC has a security function, which means that the PC can be accessed only by users (based on an access code or the like). The control unit, comprising inter alia a sound card, is equipped such that commands may also be given to the soft phone, even if for security reasons the PC is blocked (e.g. by a security code), it being possible to transfer a limited number of commands via the USB gate from the control unit.

U.S. Patent Application No. 20060072771 discloses a cross-point matrix for digital signal routing and control The matrix realized by the software code includes a plurality of configurable inputs adapted to accept one or more input signals; a plurality of configurable outputs connected via signal paths to the inputs; and a plurality of variable gain control circuits described by the code at each signal path intersection for enabling signal strength level adjustment. In a preferred embodiment, the matrix is a software interface inserted between a sound editing application and a sound card.

Unfortunately, none of these approaches address the deficiencies of the related art.

### SUMMARY

In general, embodiments of the present invention provide an approach for VM-based sound control (e.g., volume control, playback, recording, etc.) for computerized/electronic devices (e.g., personal computers (PCs), tablets, smart phones, media players, etc) in a networked computing environment (e.g. a cloud computing environment). In a typical embodiment, a system/architecture is provided that comprises a virtual machine (VM) in communication with a computerized device (e.g., a PC) over a network (e.g., a cloud computing network). The VM may comprise: a VM sound player configured to maintain a memory mapping comprising sound data and to generate a control signal based on the memory mapping; and a VM agent configured to receive the control signal from the VM sound player and to communicate the control signal to a virtual desktop agent (VDA). The computerized device may comprise: a device receiver configured to receive the control signal from the VDA over at least one computing network; a device agent configured to receive the control signal from the device receiver, and to process the control signal to yield a processed control signal; and a device sound driver configured to receive the processed control signal from the device agent and to implement the processed control signal for the computerized device. These components provide for optimal control of recording and playing back of sounds.

A first aspect of the present invention provides a system for virtual machine (VM)-based sound control of computerized devices in a networked computing environment, comprising: a VM sound player configured to maintain a memory mapping comprising sound data and to generate a control signal based on the memory mapping; and a VM agent configured to receive the control signal from the VM sound player and to communicate the control signal to a virtual desktop agent (VDA), wherein the VDA is configured to communicate the control signal to a device receiver of a computerized device over at least one computing network.

A second aspect of the present invention provides a system for virtual machine (VM)-based sound control of computerized devices in a networked computing environment, comprising: a VM, comprising: a VM sound player configured to maintain a memory mapping comprising sound data and to generate a control signal based on the memory mapping; a VM agent configured to receive the control signal from the VM sound player and to communicate the control signal to a virtual desktop agent (VDA); a computerized device, comprising: a device receiver configured to receive the control signal from the VDA over at least one computing network; a device agent configured to receive the control signal from the device receiver and to process the control signal to yield a processed control signal; and a device sound driver configured to receive the processed control signal from the device agent and to implement the processed control signal for the computerized device.

A third aspect of the present invention provides a method for virtual machine (VM)-based sound control of computerized devices in a networked computing environment, comprising: generating a control signal based on a memory mapping maintained by a VM sound player of a VM; receiving the control signal on a VM agent of the VM; sending the control signal to a virtual desktop agent (VDA) of the VM from the VM agent; sending the control signal from the VDA to a device receiver of a computerized device over at least one computing network; receiving the control signal on a device agent of the computerized device from the device receiver; processing the control signal with the device agent to yield a processed control signal; and sending the processed control signal from the device agent to a device sound driver of the computerized device.

A fourth aspect of the present invention provides a method for virtual machine (VM)-based control of sound recording for a computerized device in a networked computing environment: transmitting a sound recording control signal from a VM sound player of a VM to a cloud environment; processing the sound recording control signal with a VM agent on the VM and a device agent on a computerized device associated with the VM; starting a sound recording based on the processed sound recording control signal via a device sound driver of the computerized device; and sending sound data associated with the sound recording to the VM via the device agent.

### BRIEF DESCRIPTION OF THE DRAWINGS

These and other features of this invention will be more readily understood from the following detailed description of the various aspects of the invention taken in conjunction with the accompanying drawings in which:

FIG. 1 depicts a cloud computing node according to an embodiment of the present invention.

FIG. 2 depicts a cloud computing environment according to an embodiment of the present invention.

FIG. 3 depicts a system diagram according to an embodiment of the present invention.

FIG. 4 depicts an illustrative control table according to an embodiment of the present invention.

The drawings are not necessarily to scale. The drawings are merely schematic representations, not intended to portray specific parameters of the invention. The drawings are intended to depict only typical embodiments of the invention, and therefore should not be considered as limiting the scope of the invention. In the drawings, like numbering represents like elements.

### DETAILED DESCRIPTION OF THE INVENTION

Illustrative embodiments will now be described more fully herein with reference to the accompanying drawings, in which exemplary embodiments are shown. This disclosure may, however, be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

The terminology used herein is for the purpose of describing particular embodiments only and is not intended to be limiting of this disclosure. As used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. The word “set” is intended to mean a quantity of at least one. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the present invention provide an approach for VM-based sound control (e.g., volume control, playback, recording, etc.) for computerized/electronic devices (e.g., personal computers (PCs), tablets, smart phones, media players, etc) in a networked computing environment (e.g. a cloud computing environment). In a typical embodiment, a system/architecture is provided that comprises a virtual machine (VM) in communication with a computerized device (e.g., a PC) over a network (e.g., a cloud computing network). The VM may comprise: a VM sound player configured to maintain a memory mapping comprising sound data and to generate a control signal based on the memory mapping; a VM agent configured to receive the control signal from the VM sound player and to communicate the control signal to a virtual desktop agent (VDA). The computerized device may comprise: a device receiver configured to receive the control signal from the VDA over at least one computing network; a device agent configured to receive the control signal from the device receiver and to process the control signal to yield a processed control signal; and a device sound driver configured to receive the processed control signal from the device agent and to implement the processed control signal for the computerized device. These components provide for optimal control of

In one embodiment, aspects of the present invention may be implemented in a cloud computing environment (although it is understood that these aspects may be implemented with any type of networked computing environment now known or later developed). Cloud computing is a model of service delivery for enabling convenient, on-demand network access to a shared pool of configurable computing resources (e.g. networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed, automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active consumer accounts). Resource usage can be monitored, controlled, and reported providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based email). The consumer does not manage or control the underlying cloud infrastructure including network, servers, operating systems, storage, or even individual application capabilities, with the possible exception of limited consumer-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application-hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure comprising a network of interconnected nodes.

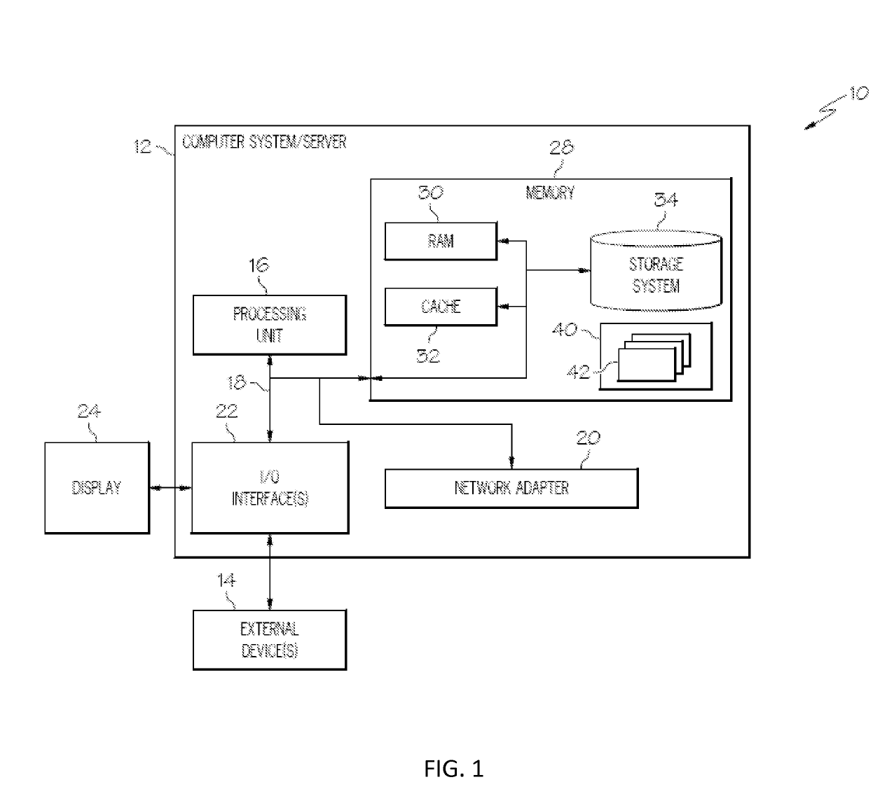

Referring now to FIG. 1, a schematic of an example of a computing node (e.g., cloud computing mode) is shown. Computing node 10 is only one example of a suitable computing node and is not intended to suggest any limitation as to the scope of use or functionality of embodiments of the invention described herein. Regardless, computing node 10 is capable of being implemented and/or performing any of the functionality set forth hereinabove.

In computing node 10, there is a computer system/server 12, which is operational with numerous other general purpose or special purpose computing system environments or configurations. Examples of well-known computing systems, environments, and/or configurations that may be suitable for use with computer system/server 12 include, but are not limited to, personal computer systems, server computer systems, thin clients, thick clients, hand-held or laptop devices, mobile devices, global positioning systems (GPS), GPS-enable devices, multiprocessor systems, microprocessor-based systems, set top boxes, programmable consumer electronics, network PCs, minicomputer systems, mainframe computer systems, and distributed computing environments that include any of the above systems or devices, and the like.

Computer system/server 12 may be described in the general context of computer system-executable instructions, such as program modules, being executed by a computer system. Generally, program modules may include routines, programs, objects, components, logic, data structures, and so on, which perform particular tasks or implement particular abstract data types. Computer system/server 12 may be practiced in distributed computing environments where tasks are performed by remote processing devices that are linked through a communications network. In a distributed computing environment, program modules may be located in both local and remote computer system storage media including memory storage devices.

As shown in FIG. 1, computer system/server 12 in computing node 10 is shown in the form of a general-purpose computing device. The components of computer system/server 12 may include, but are not limited to, one or more processors or processing units 16, a system memory 28, and a bus 18 that couples various system components including system memory 28 to processor 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system/server 12 typically includes a variety of computer system readable media. Such media may be any available media that is accessible by computer system/server 12, and it includes both volatile and non-volatile media, removable and non-removable media.

System memory 28 can include computer system readable media in the form of volatile memory, such as random access memory (RAM) 30 and/or cache memory 32. Computer system/server 12 may further include other removable/non-removable, volatile/non-volatile computer system storage media. By way of example only, storage system 34 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM, or other optical media can be provided. In such instances, each can be connected to bus 18 by one or more data media interfaces. As will be further depicted and described below, memory 28 may include at least one program product having a set (e.g., at least one) of program modules that are configured to carry out the functions of embodiments of the invention.

The embodiments of the invention may be implemented as a computer readable signal medium, which may include a propagated data signal with computer readable program code embodied therein (e.g., in baseband or as part of a carrier wave). Such a propagated signal may take any of a variety of forms including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium including, but not limited to, wireless, wireline, optical fiber cable, radio-frequency (RF), etc., or any suitable combination of the foregoing.

Program/utility 40, having a set (at least one) of program modules 42, may be stored in memory 28 by way of example, and not limitation, as well as an operating system, one or more application programs, other program modules, and program data. In general, program/utility 40 performs the function of the present invention as described herein. Each of the operating system, one or more application programs, other program modules, and program data or some combination thereof, may include an implementation of a networking environment. Program modules 42 generally carry out the functions and/or methodologies of embodiments of the invention as described herein.

Computer system/server 12 may also communicate with one or more external devices 14 such as a keyboard, a pointing device, a display 24, etc.; one or more devices that enable a consumer to interact with computer system/server 12; and/or any devices (e.g., network card, modem, etc.) that enable computer system/server 12 to communicate with one or more other computing devices. Such communication can occur via I/O interfaces 22. Still yet, computer system/server 12 can communicate with one or more networks such as a local area network (LAN), a general wide area network (WAN), and/or a public network (e.g., the Internet) via network adapter 20. As depicted, network adapter 20 communicates with the other components of computer system/server 12 via bus 18. It should be understood that although not shown, other hardware and/or software components could be used in conjunction with computer system/server 12. Examples include, but are not limited to: microcode, device drivers, redundant processing units, external disk drive arrays, RAID systems, tape drives, and data archival storage systems, etc.

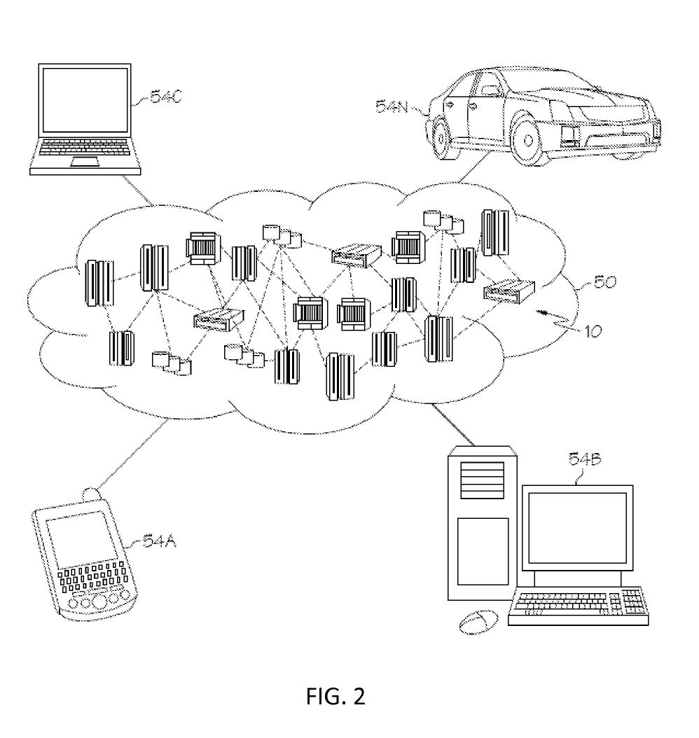

Referring now to FIG. 2, illustrative cloud computing environment 50 is depicted. As shown, cloud computing environment 50 comprises one or more cloud computing nodes 10 with which local computing devices used by cloud consumers, such as, for example, personal digital assistant (PDA) or cellular telephone 54A, desktop computer 54B, laptop computer 54C, and/or automobile computer system 54N may communicate. Nodes 10 may communicate with one another. They may be grouped (not shown) physically or virtually, in one or more networks, such as private, community, public, or hybrid clouds as described hereinabove, or a combination thereof. This allows cloud computing environment 50 to offer infrastructure, platforms, and/or software as services for which a cloud consumer does not need to maintain resources on a local computing device. It is understood that the types of computing devices 54A-N shown in FIG. 2 are intended to be illustrative only and that computing nodes 10 and cloud computing environment 50 can communicate with any type of computerized device over any type of network and/or network addressable connection (e.g., using a web browser).

It is further understood that although an illustrative embodiment discussed herein involves the use of components (e.g., virtual desktop agents, virtual desktop infrastructure, etc.) by LG®, Inc. and/or Citrix® Systems, Inc., this need not be the case. Rather, components with similar functionality could be obtained from other sources/suppliers.

Regardless, as indicated above, embodiments of the present invention provide an approach to control the sound of a computerized device (e.g., a PC, a laptop computer, a tablet device, a media player, etc.) or the like using VM technology. In so doing, embodiments of the present invention provide an approach to record sounds properly. In a cloud computing environment, a VM sound player agent's volume data may be provided to the computerized device via a virtual desktop agent (VDA) (e.g., the Citrix VDA). The computerized device receives the data via a device receiver (e.g., a Citrix receiver) and sends data to the device's agent (e.g., a cloud PC agent). The device's sound driver then adjusts the sound volume based on this data. In another embodiment, the VM's sound player may send a sound (e.g., voice) recording control signal to the device's agent and to the VM agent (e.g., cloud VM agent). Both agents may perform the operation of the PC agent for handling the recording. Thus, by controlling the device agent and/or the VM agent, accurate/efficient playback and recording may be performed.

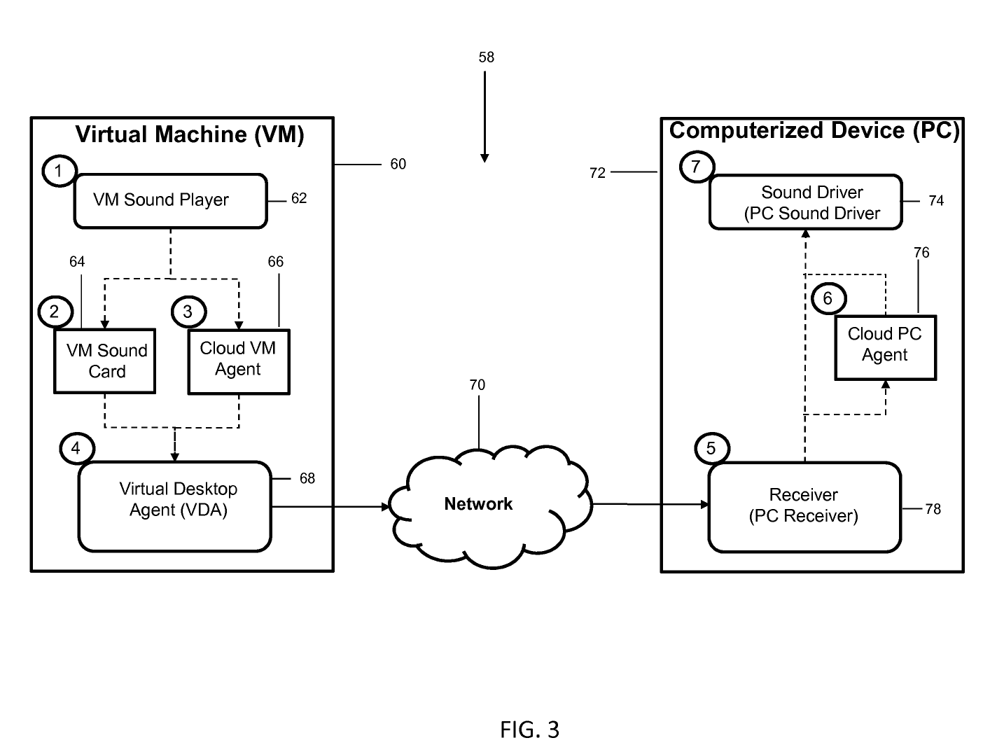

Referring now to FIG. 3, a system 58 for implementing the functionality discussed herein according to an embodiment of the present invention is shown. It is understood that the teachings recited herein may be practiced within any type of networked computing environment (e.g., a cloud computing environment). Regardless, among other functions, system 58 (among other things): provides management and coordination of an computerized device's sound playback and/or recording functions.

As depicted, VM generally comprises a VM sound player 62 coupled to a VM sound card 64 and a VM agent 66 (e.g., cloud VM agent), which both feed virtual desktop agent (e.g., Citrix VDA). Computerized device (e.g., a PC) 72 may comprise a device sound driver 74 coupled to a device agent 76 (e.g., a cloud PC agent), receiver 78 (e.g., a Citrix/PC receiver). In general, these components may have the following functionality:

VM sound player 62 is configured to create, maintain, and/or utilize a memory mapping for the sound player and for VM Agent 66 to process and/or communicate to VDA 68. The sound volume control signal for the VM sound player 62 and for any sound recordings may be stored in this memory mapping.

VM sound card 64 may be a standard sound card that is used by any type of virtual machine now known or later developed.

VM agent 66 is an agent that controls communications involving VM 60 and computerized device 72 data. As such, VM agent 66 is located on VM 60 and relays data between applications and devices (e.g., PCs).

VDA 68 is a virtual desktop agent that creates a communications channel to computerized device 72 via network 70.

Device Receiver/agent 78 connects computerized device 72 to VM 60 through the aforementioned communications channel via network. 70.

Device agent 76 processes the control signal received from VM 60 (e.g., via device receiver 78) and sends the same to device sound driver 74. Along these lines, device agent 76 may provide performance and status information of the computerized device 72 (e.g., to VM 60 for optimal sound control).

Device sound card/driver 74 represents the sound hardware on computerized device 72 that receives and implements a processed control signal from device agent 76.

Under system 58, there are multiple /embodiments of the present invention. In one embodiment, a function is provided that controls the volume of the device sound card using the VM 60. In another embodiment, after a sound recording is performed on computerized device 72, corresponding data may be converted to data traffic and send it through a transport (e.g., a TCP transport).

Along these lines, device sound card/driver 74 may implement sound function (e.g., volume) control which may be implemented as follows. When VM sound player 62 sends volume data (e.g., as a control signal) through VM agent 66, the data may be sent to the computerized device 72 through an ICA channel created by VDA 68. The volume control data, which is received by the device receiver 78, is transmitted through device agent 76 where it is processed and used to control the sound of computerized device 72 via device sound driver/card 74.

Similarly, at the VDI, recorded data may be transferred by this method. Specifically, VM sound player 62 may transmit a sound (e.g., voice) recording control signal to a cloud environment 70 or the like. VM agent 66 and device agent 76 may process the signal and start recording through the device sound driver/card 74. When the sound recording is complete, the data may remain in computerized device 72, and PC agent 76 may send the recorded data through the ICA to VM 60. Thus, the recording approach of the embodiments of the present invention will not be affected by the network status.

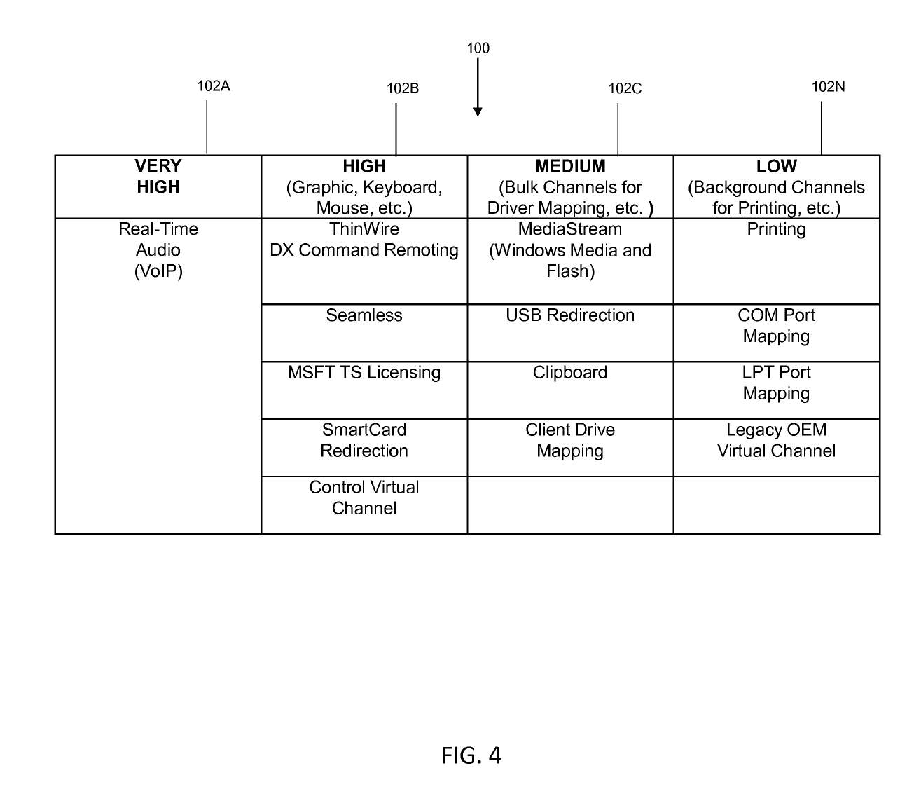

Referring now to FIG. 4, a channel control table 100 according to an embodiment of the present invention is shown. As depicted, table 100 comprises columns 102A-N that list items/action types according to resource consumption. As seen, very high operation column 102A indicates real-time audio (e.g., VoIP) operations; high operation column 102B (e.g., graphics, keyboard, mouse, etc.) lists thin wire and DX command remoting operations, seamless operations, MSFT TS licensing operations, smart card redirection operations, and control virtual channel operations; medium operation column 102C (e.g., bulk channels, etc.) lists media stream operations, USB redirection operations, clipboard operations, client drive mapping operations; and low operations channel 102N (e.g., background channels for printing, etc.). Such a table 100 may be used to maintain sound data mappings or the like based on bandwidth and/or resource consumption.

Regardless, based on the foregoing (in one embodiment) system 58 (e.g., the components thereof) may: create a memory mapping using the VM sound player; generate a control signal based on the memory mapping maintained by a VM sound player of a VM; receive the control signal on a VM agent of the VM; send the control signal to a virtual desktop agent (VDA) of the VM from the VM agent; create a communications channel to a device receiver from the VDA; send the control signal from the VDA to a device receiver of a computerized device over at least one computing network; receive the control signal on a device agent of the computerized device from the device receiver; process the control signal with the device agent to yield a processed control signal; send the processed control signal from the device agent to a device sound driver of the computerized device; implement the processed control signal to control at least one sound function of the computerized device, the at least one sound function pertaining to a recording of a sound or a playing back of a sound recording.

While shown and described herein as VM-based sound control solution, it is understood that the invention further provides various alternative embodiments. For example, in one embodiment, the invention provides a computer-readable/useable medium that includes computer program code to enable a computer infrastructure to provide VM-based sound control as discussed herein. To this extent, the computer-readable/useable medium includes program code that implements each of the various processes of the invention. It is understood that the terms computer-readable medium or computer-useable medium comprise one or more of any type of physical embodiment of the program code. In particular, the computer-readable/useable medium can comprise program code embodied on one or more portable storage articles of manufacture (e.g., a compact disc, a magnetic disk, a tape, etc.), on one or more data storage portions of a computing device, such as memory 28 (FIG. 1) and/or storage system 34 (FIG. 1) (e.g., a fixed disk, a read-only memory, a random access memory, a cache memory, etc.).

In another embodiment, the invention provides a method that performs the process of the invention on a subscription, advertising, and/or fee basis. That is, a service provider, such as a Solution Integrator, could offer to provide VM-based sound control functionality. In this case, the service provider can create, maintain, support, etc., a computer infrastructure, such as computer system 12 (FIG. 1) that performs the processes of the invention for one or more consumers. In return, the service provider can receive payment from the consumer(s) under a subscription and/or fee agreement and/or the service provider can receive payment from the sale of advertising content to one or more third parties.

In still another embodiment, the invention provides a computer-implemented method for VM-based sound control. In this case, a computer infrastructure, such as computer system 12 (FIG. 1), can be provided and one or more systems for performing the processes of the invention can be obtained (e.g., created, purchased, used, modified, etc.) and deployed to the computer infrastructure. To this extent, the deployment of a system can comprise one or more of: (1) installing program code on a computing device, such as computer system 12 (FIG. 1), from a computer-readable medium; (2) adding one or more computing devices to the computer infrastructure; and (3) incorporating and/or modifying one or more existing systems of the computer infrastructure to enable the computer infrastructure to perform the processes of the invention.

As used herein, it is understood that the terms “program code” and “computer program code” are synonymous and mean any expression, in any language, code, or notation, of a set of instructions intended to cause a computing device having an information processing capability to perform a particular function either directly or after either or both of the following: (a) conversion to another language, code, or notation; and/or (b) reproduction in a different material form. To this extent, program code can be embodied as one or more of: an application/software program, component software/a library of functions, an operating system, a basic device system/driver for a particular computing device, and the like.

A data processing system suitable for storing and/or executing program code can be provided hereunder and can include at least one processor communicatively coupled, directly or indirectly, to memory elements through a system bus. The memory elements can include, but are not limited to, local memory employed during actual execution of the program code, bulk storage, and cache memories that provide temporary storage of at least some program code in order to reduce the number of times code must be retrieved from bulk storage during execution. Input/output and/or other external devices (including, but not limited to, keyboards, displays, pointing devices, etc.) can be coupled to the system either directly or through intervening device controllers.

Network adapters also may be coupled to the system to enable the data processing system to become coupled to other data processing systems, remote printers, storage devices, and/or the like, through any combination of intervening private or public networks. Illustrative network adapters include, but are not limited to, modems, cable modems, and Ethernet cards.

The foregoing description of various aspects of the invention has been presented for purposes of illustration and description. It is not intended to be exhaustive or to limit the invention to the precise form disclosed and, obviously, many modifications and variations are possible. Such modifications and variations that may be apparent to a person skilled in the art are intended to be included within the scope of the invention as defined by the accompanying claims.

What is claimed is:

1. A system for virtual machine (VM)-based sound control of computerized devices in a networked computing environment, comprising:
a VM sound player configured to maintain a memory mapping comprising sound data and to generate a control signal based on the memory mapping; and
a VM agent configured to receive the control signal from the VM sound player and to communicate the control signal to a virtual desktop agent (VDA), wherein the VDA is configured to communicate the control signal to a device receiver of a computerized device over at least one computing network.

2. The system of claim 1, the control signal facilitating control of at least one sound function of the computerized device, and the at least one sound function pertaining to a recording of a sound or a playing back of a sound recording.

3. The system of claim 1, the VM sound player, the VM agent, and the VDA being implemented in a VM.

4. The system of claim 1, further comprising a device agent configured to receive and process the control signal as received from the device receiver to yield a processed control signal.

5. The system of claim 4, further comprising a device sound driver configured to receive and implement the processed control signal.

6. The system of claim 5, the device receiver, the device agent, and the device sound driver being implemented in the computerized device.

7. The system of claim 1, the at least one computing network comprising a cloud computing network, and the VM agent being a cloud VM agent.

8. The system of claim 1, the computerized device comprising at least one of the following: a personal computer, a laptop computer, a smart phone, an electronic tablet, or a media playing device.

9. A system for virtual machine (VM)-based sound control of computerized devices in a networked computing environment, comprising:
a VM, comprising:
a VM sound player configured to maintain a memory mapping comprising sound data and to generate a control signal based on the memory mapping;
a VM agent configured to receive the control signal from the VM sound player and to communicate the control signal to a virtual desktop agent (VDA);
a computerized device, comprising:
a device receiver configured to receive the control signal from the VDA over at least one computing network;
a device agent configured to receive the control signal from the device receiver, and to process the control signal to yield a processed control signal; and
a device sound driver configured to receive the processed control signal from the device agent and to implement the processed control signal for the computerized device.

10. The system of claim 9, the control signal facilitating control of at least one sound function of the computerized device and the at least one sound function pertaining to a recording of a sound or a playing back of a sound recording.

11. The system of claim 9, the VM agent being a cloud VM agent and the device agent being a cloud device agent.

13. The system of claim 9, the at least one computing network comprising a cloud computing network.

14. The system of claim 9, the VDA being configured to create a communications channel with the computerized device.

15. A method for virtual machine (VM)-based sound control of computerized devices in a networked computing environment, comprising:
generating a control signal based on a memory mapping maintained by a VM sound player of a VM;
receiving the control signal on a VM agent of the VM;
sending the control signal to a virtual desktop agent (VDA) of the VM from the VM agent;
sending the control signal from the VDA to a device receiver of a computerized device over at least one computing network;
receiving the control signal on a device agent of the computerized device from the device receiver;
processing the control signal with the device agent to yield a processed control signal; and
sending the processed control signal from the device agent to a device sound driver of the computerized device.

16. The method of claim 15, further comprising implementing the processed control signal to control at least one sound function of the computerized device, the at least one sound function pertaining to a recording of a sound or a playing back of a sound recording.

17. The method of claim 15, further comprising creating a communications channel to the device receiver from the VDA.

18. The method of claim 15, the at least one computing network comprising a cloud computing network, the VM agent comprising a cloud VM agent, and the device agent comprising a cloud device agent.

19. The method of claim 15, the control signal comprising control data that is based on the data maintained in the memory mapping by the VM sound player.

20. A method for virtual machine (VM)-based control of a sound recording for a computerized device in a networked computing environment:
transmitting a sound recording control signal from a VM sound player of a VM to a cloud environment;
processing the sound recording control signal with a VM agent on the VM and a device agent on a computerized device associated with the VM;
starting a sound recording based on the processed sound recording control signal via a device sound driver of the computerized device; and
sending sound data associated with the sound recording to the VM via the device agent.
